(19) United States
(12) Patent Application Publication
(10) Pub. No.: US 2018/0269885 A1
(43) Pub. Date: Sep. 20, 2018

(54) OSCILLATOR, SEMICONDUCTOR DEVICE AND WIRELESS COMMUNICATION APPARATUS

(71) Applicant: KABUSHIKI KAISHA TOSHIBA, Minato-ku (JP)

(72) Inventors: Satoshi KONDO, Kawasaki (JP); Akihide Sai, Yokohama (JP); Masanori Furuta, Odawara (JP)

(73) Assignee: KABUSHIKI KAISHA TOSHIBA, Minato-ku (JP)

(21) Appl. No.: 15/705,949

(22) Filed: Sep. 15, 2017

(30) Foreign Application Priority Data
Mar. 17, 2017 (JP) 2017-053669

(51) Int. Cl. H03L 7/099; H04B 1/16; H03L 7/091; H03K 3/84

(52) U.S. Cl. CPC H03L 7/0992; H04B 1/16; H03L 2207/50; H03K 3/84; H03L 7/091

(57) ABSTRACT

An oscillator has an oscillator, an integer phase detector, a random number generator, an edge selector, a fractional phase detector, an offset correction arithmetic unit, and a phase error generator. The oscillator generates an oscillation signal having an oscillation frequency in accordance with a phase error signal. The integer phase detector detects an integer phase of the oscillation signal. The random number generator generates a random number. The edge selector outputs a phase difference signal indicating a phase difference between a phase of a reference signal and a phase of the oscillation signal, or indicating a phase difference acquired by offsetting the phase difference. The fractional phase detector detects a fractional phase of the oscillation signal based on the phase difference signal. The offset correction arithmetic unit computes an offset correction value in accordance with the random number. The phase error generator generates the phase error signal.

### CROSS REFERENCE TO RELATED APPLICATIONS

This application is based upon and claims the benefit of priority from the prior Japanese Patent Application No. 2017-53669, filed on Mar. 17, 2017, the entire contents of which are incorporated herein by reference.

### FIELD

Embodiments relate to an oscillator, a semiconductor device, and a wireless communication apparatus.

### BACKGROUND

A technique called dithering is known. The dithering is a technique to add an offset to the input signal of an A/D converter, a time-to-digital converter (TDC), etc., and to subtract an offset equivalent to the added offset from a converted code signal to randomize converter nonlinearity. The dithering can be applied to ADPLL (All Digital Phase-Locked Loop) to decrease further fractional spurious caused by TDC nonlinearity.

The known dithering has a problem of taking long time to perform dither processing, with complicated hardware. It is expected to perform the dithering at high speeds with a simple configuration in view of addition of the dithering to an oscillator built in a consumer communication apparatus.

### BRIEF DESCRIPTION OF THE DRAWINGS

FIG. 1 is a block diagram schematically showing the configuration of an oscillator 1 according to a first embodiment;

FIG. 2 is a graph showing TDC nonlinear characteristics;

FIG. 3 is circuit diagram showing an example of the internal configuration of an edge selector;

FIG. 4 is an operation timing chart of the edge selector of FIG. 3;

FIG. 5 is a block diagram schematically showing the configuration of an oscillator 1 according to a second embodiment;

FIG. 6 is an illustration showing the state of dither addition at a gain α=0.5 (duty ratio of 50%);

FIG. 7 is an illustration showing the state of dither addition at a duty ratio other than 50%;

FIG. 8 is a circuit diagram showing the internal configuration of an edge selector of FIG. 5;

FIG. 9 is an operation timing chart of the edge selector of FIG. 8;

FIG. 10 is a block diagram showing the internal configurations of reception circuitry having an oscillator of ADPLL configuration in the first or the second embodiment and of a wireless communication apparatus;

FIG. 11 shows an example of wireless communication between a PC and a mouse; and

FIG. 12 shows an example of wireless communication between a wearable terminal and a host device.

### DETAILED DESCRIPTION

An oscillator according to one embodiment has an oscillator, an integer phase detector, a random number generator, an edge selector, a fractional phase detector, an offset correction arithmetic unit, and a phase error generator. The oscillator unit to generate an oscillation signal having an oscillation frequency in accordance with a phase error signal. The integer phase detector to detect an integer phase of the oscillation signal. The random number generator to generate a random number. The edge selector, based on the random number, to output a phase difference signal indicating a phase difference between a phase of a reference signal and a phase of the oscillation signal, or indicating a phase difference acquired by offsetting the phase difference. The fractional phase detector to detect a fractional phase of the oscillation signal based on the phase difference signal. The offset correction arithmetic unit to compute an offset correction value in accordance with the random number. The phase error generator to generate the phase error signal based on the integer phase, the fractional phase, the offset correction value, and the reference phase.

Hereinafter, embodiments of the present disclosure will be explained with reference to the drawings. In the accompanying drawings of the present specification, for simplicity of drawings and easy understanding, the scale, the ratio of height to width, etc. are appropriately modified or enlarged from actual ones.

Shapes and geometrical conditions, and also their degrees used in this specification are defined. For example, the terms such as “parallel”, “orthogonal” and “the same”, the values of length and angle, etc. are, not to be limited to the strict sense of the terms, but interpreted to such an extent that a similar function can be expected.

### FIRST EMBODIMENT

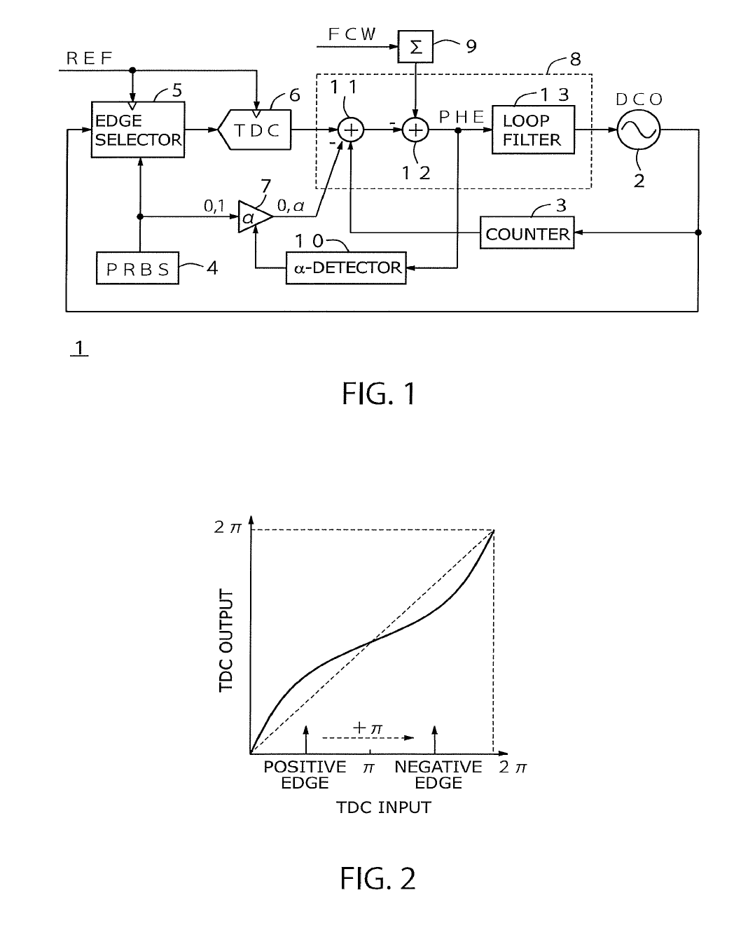

FIG. 1 is a block diagram schematically showing the configuration of an oscillator 1 according to a first embodiment. The oscillator 1 of FIG. 1 can be used as, for example, an oscillator 1 of a wireless communication apparatus such as a receiver and a transmitter. The use of the oscillator 1 of FIG. 1 is not limited to the wireless communication apparatus. The oscillator 1 of FIG. 1 stabilizes the oscillation frequency of an oscillation signal under digital PLL control.

The oscillator 1 of FIG. 1 is provided with an oscillator unit 2, an integer phase detector 3, a random number generator (PRBS: Pseudo-Random Bit Sequence) 4, an edge selector 5, a fractional phase detector 6, an offset correction arithmetic unit 7, a phase error generator 8, and a reference phase generator 9.

The oscillator unit 2 generates an oscillation signal having an oscillation frequency in accordance with a phase error signal. The oscillator unit 2 is a digitally-controlled oscillator (DCO) 2 configured with an LC oscillator, a ring oscillator, etc. The DCO 2 is capable of controlling the oscillation frequency with a digital control code FCW.

The integer phase detector 3 detects an integer phase of the oscillation signal of the DCO 2. The integer phase detector 3 can be configured with a counter 3, for example.

The random number generator 4 generates a random number. The random number generated by the random number generator 4 may not only be a random number in the strict sense but may also be a pseudo-random number generated by using generating polynomials or the like. In the present embodiment, the pseudo-random numbers is also expressed as a random number. The random number generated by the random number generator 4 is 0 or 1 randomly appeared.

Based on the random number generated by the random number generator 4, the edge selector 5 outputs a phase difference signal that indicates a phase difference between the phase of a reference signal REF and the phase of the oscillation signal or that indicates a phase difference that is acquired by offsetting the above phase difference. In more specifically, the edge selector 5 determines whether to offset the phase difference by +π, based on the random number generated by the random number generator 4. The internal configuration of the edge selector 5 will be described later.

The fractional phase detector 6 detects a fractional phase of the oscillation signal based on the phase difference signal output from the edge selector 5. The fractional phase detector 6 is configured with a time-to-digital converter (TDC) 6.

The offset correction arithmetic unit 7 computes an offset correction value in accordance with the random number generated by the random number generator 4. The offset correction arithmetic unit 7 has a multiplier 7 that multiplies a gain α, which is decided based on the phase error signal, by the random number. The output of the multiplier 7 becomes the offset correction value. It is desirable to adjust the gain α so that a phase noise of the oscillation signal becomes minimum. The gain α is detected by an α-detector 10 based on a phase error signal PHE which will be described later.

The phase error generator 8 generates a phase error signal based on the integer phase, the fractional phase, the offset correction value, and a reference phase. The phase error generator 8 has a first adder 11, a second adder 12, and a loop filter 13. The first adder 11 outputs a signal acquired by adding output signals of the TDC 6, the multiplier 7, and the counter 7. In more detail, the first adder 11 subtracts the offset correction value from the output signal of the TDC 6 to acquire a fractional phase having an offset cancelled out. Moreover, the first adder 11 adds the integer phase to the fractional phase.

The second adder 12 outputs a signal PHE that is a difference between the output signal of the first adder 11 and the reference phase generated by the reference phase generator 9. The signal PHE corresponds to the phase error signal. The loop filter 13 removes a noise component included in the phase error signal. The output signal of the loop filter 13 is supplied to the DCO 2, as an oscillation control signal. Based on the oscillation control signal, the DCO 2 controls the oscillation frequency of the oscillation signal.

Subsequently, the operation of the oscillator 1 of FIG. 1 is explained. In a normal operation, the edge selector 5 outputs a phase difference signal between the reference signal and a positive edge of the oscillation signal of the DCO 2. The TDC 6 performs feedback control so that the phase difference between the reference signal and the positive edge of the oscillation signal of the DCO 2 becomes zero.

If the random number generated by the random number generator 4 is zero, even in a dithering operation, in the same manner as in the normal operation, the edge selector 5 supplies, to the TDC 6, the phase difference signal between the reference signal and the positive edge of the oscillation signal of the DCO 2. On the other hand, if the random number generated by the random number generator 4 is 1, the edge selector 5 supplies, to the TDC 6, a phase difference signal between the reference signal and a negative edge of the DCO 2, which is, in more specifically, a negative edge input next to a positive edge of the oscillation signal.

FIG. 2 is a graph showing nonlinear characteristics of the TDC 6. The abscissa and the ordinate of FIG. 2 indicate an input phase and an output phase, respectively, of the TDC 6. If the TDC 6 has linear characteristics, the relationship between the input phase and the output phase of the TDC 6 must be shown as a straight-line graph such as a broken line shown in FIG. 2. However, practically, due to variation in electrical characteristics of component parts and the like, the relationship between the input phase and the output phase of the TDC 6 becomes nonlinear. In the example of FIG. 2, from 0 to π in input phase, the output phase advances too much, whereas, from π to 2π in input phase, the output phase is slightly delayed. In the present embodiment, even if the TDC 6 has nonlinear characteristics such as shown in FIG. 2, by randomly determining whether to shift the phase difference signal to be supplied to the TDC 6 by +π, dithering processing is performed to randomize the nonlinearity of the TDC 6 to make the nonlinearity closer to linearity.

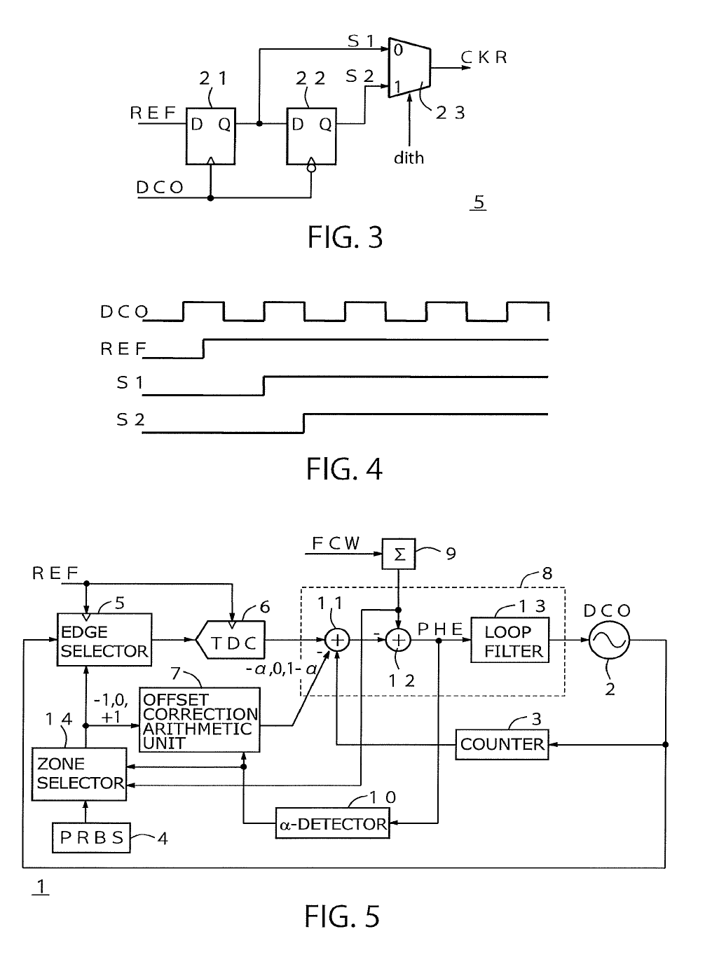

FIG. 3 is a circuit diagram showing an example of the internal configuration of the edge selector 5. FIG. 4 is an operation timing chart of the edge selector 5 of FIG. 3. The edge selector 5 of FIG. 3 has two-stage flip-flops (hereinafter, F/F) 21 and 22, and a multiplexer 23. The initial stage F/F 21 holds the reference signal at a positive edge of the oscillation signal of the DCO 2. The next-stage F/F 22 holds a hold signal S1 of the initial stage F/F 21 at a negative edge of the oscillation signal of the DCO 2. The multiplexer 23 selects either the hold signal S1 of the first stage F/F 21 or a hold signal S2 of the next-stage F/F 22, by means of the random number.

As shown in FIG. 4, the hold signal S1 rises at a positive edge of the oscillation signal of the DCO 2. The hold signal S2 rises after the rise of the hold signal S1 by a half cycle period. When the random number is zero (in the normal operation), the edge selector 5 supplies the hold signal S1 to the TDC 6. When the random number is 1 (in the dithering operation), the edge selector 5 supplies the hold signal S2 having a phase advance from the hold signal S1 by +π, to the TDC 6.

In FIG. 3, the initial-stage F/F 21 performs the hold operation at the positive edge of the oscillation signal of the DCO 2 and the next-stage F/F 22 performs the hold operation at the negative edge thereof. However, the F/Fs 21 and 22 may perform the hold operations at negative and positive edges of the oscillation signal, respectively, which are the reverse of the edges described above.

As described above, the phase difference signal output from the edge selector 5 varies randomly in accordance with the random number generated by the random number generator 4. In more detail, whether to shift the phase difference signal by +π is randomly determined. Accordingly, when the oscillator 1 of FIG. 1 is operated for a long time, the nonlinearity of the TDC 6 is randomized to make the input and output characteristics of the TDC 6 closer to be linear.

Although the TDC 6 does not always have such input and output characteristics as shown in FIG. 2, the characteristics shown in FIG. 2 has the highest level of nonlinearity. Therefore, by randomly determining with the random number whether to shift the phase difference signal by +π, it is possible to make the input and output characteristics of the TDC 6 closer to be linear such as indicated by the broken line in FIG. 2.

The first adder 11 in the phase error generator 8 subtracts the offset correction value, which is acquired by multiplying the random number by the gain α, from the output signal of TDC 6 to remove the effect of phase shift performed by the edge selector 5. The gain α is the phase difference between the positive edge and the negative edge of the oscillation signal of the DCO 2, or a duty ratio of the oscillation signal, corresponding to +π in an ideal state. Due to a large effect of variation in circuitry and the like, if the phase difference between the positive and negative edges is not +π, by correcting the value of the gain α so as to make smaller the phase error signal PHE, dithering can be performed without increasing phase noises of the TDC 6.

The correction of the gain α can be performed with a variety of algorithms such as an LMS algorithm to take temporal mean. Different from the case where the oscillator 1 is configured with a variable delay element, since the edges of the oscillation signal of the DCO 2 are used as delay amounts, variation is small and hence the time cost for correction can be reduced.

As described above, in the first embodiment, since whether to shift the phase difference signal to be input to the

TDC 6 by +π is randomly determined with the random number, the nonlinearity of the TDC 6 can be randomized and, as a result, the linearity of the TDC 6 can be improved.

Moreover, in the first embodiment, since the nonlinearity of the TDC 6 can be randomized only with binary random numbers, the linearity of the TDC 6 can be improved at high speeds without complicating the internal configuration of the oscillator 1.

### SECOND EMBODIMENT

The edge selector 5 according to the first embodiment determines with the random number whether to shift the phase difference signal by +π. However, when the phase difference signal is shifted by +π, the phase of the phase difference signal shifted by +π may exceed 2π. In order to cover that, the TDC 6 requires an input range from 0 to 3π. It is however difficult to widen the input range of TDC 6.

In view of above, in the present embodiment, two pairs (0, +απ ) and (0, (α−1)π) are provided as the phase shift amount of the edge selector 5, and either one of the pairs is selected in accordance with the magnitude of the phase difference signal. The gain α is a duty ratio of the oscillation signal of the DCO 2.

The gain α is obtained by using the relationship between the input phase of the TDC 6 and the ADPLL reference phase that both phases are in phase during phase locking.

FIG. 5 is a block diagram schematically showing the configuration of an oscillator 1 according to the second embodiment. The oscillator 1 of FIG. 5 is provided with a zone selector (phase-shift direction selector) 14 in addition to the components of FIG. 1.

The zone selector 14 generates a signal that indicates a phase shift direction in the edge selector 5 based on the reference phase and the random number. In more specifically, the zone selector 14 outputs any one of the values −1, 0 and +1. The value −1 indicates an adjustment to make smaller the phase difference. The value +1 indicates an adjustment to make larger the phase difference. The value 0 indicates no adjustments to the phase difference.

In order to remove an offset from the output of the TDC 6, the offset correction arithmetic unit 7 computes the offset. In more specifically, the offset correction arithmetic unit 7 outputs −α, 0 or 1−α, as the offset.

With (1−α)π as a reference, if the phase difference is smaller than (1−α)π, the edge selector 5 corrects the phase difference signal by dither with a combination of (0, +απ), whereas if the phase difference is equal to or larger than (1−α)π, the edge selector 5 corrects the phase difference signal by dither with a combination of (0, (α−1)π). The corrected signal is supplied to the TDC 6.

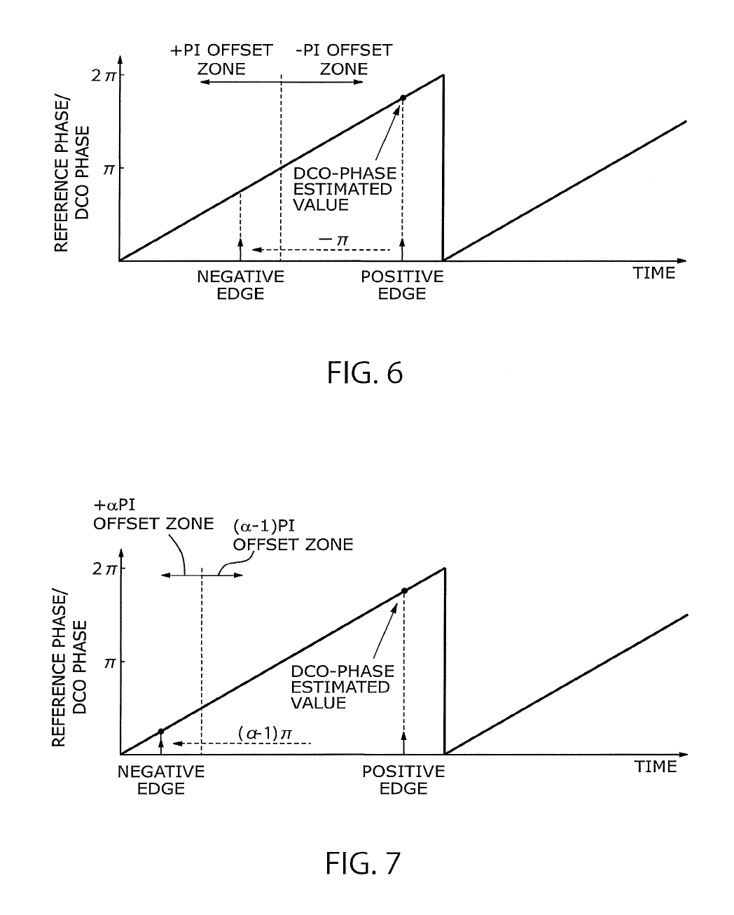

FIG. 6 is an illustration showing the state of dither addition at a gain α=0.5 (duty ratio of 50%). FIG. 6 shows the case where the reference phase is equal to or larger than +π. In this case, since the phase of the oscillation signal of the DCO 2 is also considered to be equal to or larger than +π, in the case of phase shift of +π using a negative edge next to a positive edge of the oscillation signal, the TDC 6 requires an input range of 2π or larger. However, in the present embodiment, phase shift of −π is performed with selection of a negative edge just before the positive edge of the oscillation signal, so that the input range required for the TDC 6 can be narrowed.

FIG. 7 is an illustration showing the state of dither addition at a duty ratio other than 50%. FIG. 7 shows the case where the reference phase is equal to or larger than (1−α)π. In this case, since the phase of the oscillation signal of the DCO 2 is also considered to be equal to or larger than (1−α)π, in the case of phase shift of +απ using a negative edge next to a positive edge of the oscillation signal, the TDC 6 requires an input range of 2π or larger. However, in the present embodiment, phase shift of (α−1)π is performed with selection of a negative edge just before the positive edge of the oscillation signal, so that the input range required for the TDC 6 can be narrowed.

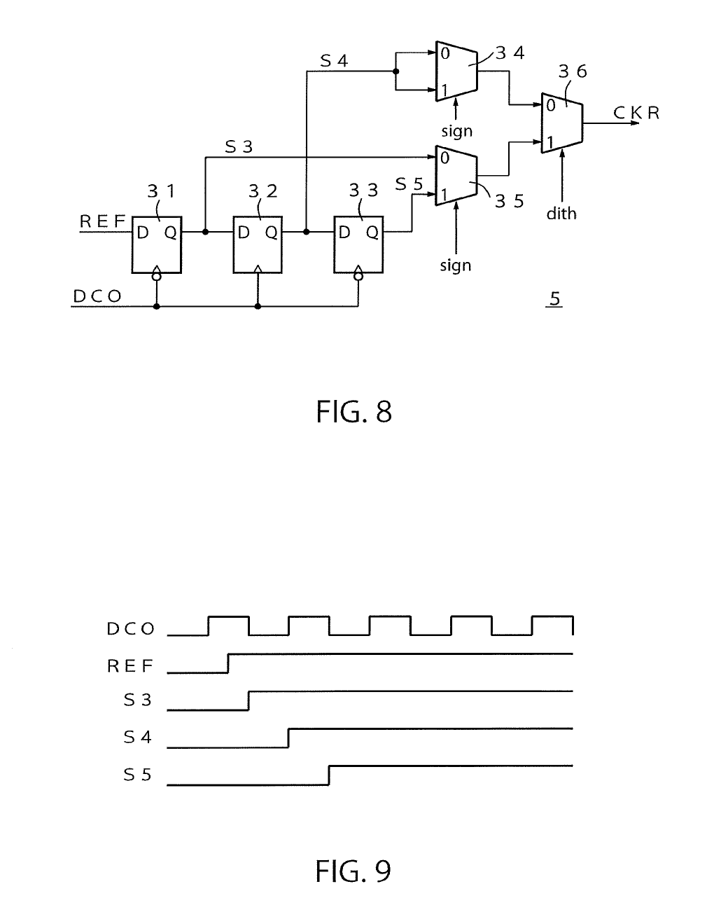

FIG. 8 is a circuit diagram showing the internal configuration of the edge selector 5 of FIG. 5. FIG. 9 is an operation timing chart of the edge selector 5 of FIG. 8. The edge selector 5 of FIG. 8 has three-stage F/Fs 31 to 33 and first to third multiplexers 34 to 36. The initial stage F/F 31 outputs a hold signal S3 that is the reference signal held at a negative edge of the oscillation signal of the DCO 2. The second stage F/F 32 outputs a hold signal S4 that is the hold signal S3 of the initial stage F/F 31 held at a positive edge of the oscillation signal. The third stage F/F 33 outputs a hold signal S5 that is the hold signal S4 of the second stage F/F 32 held at a negative edge of the oscillation signal.

Since, both of two inputs of the first multiplexer 34 are input with the hold signal S4, the first multiplexer 34 always outputs the hold signal S4. The second multiplexer 35 outputs either the hold signal S3 or S5 depending on the sign of the output signal of the zone selector 14. If the output signal of the zone selector 14 is +1 or −1, the third multiplexer 36 outputs the output signal of the second multiplexer 35. If the output signal of the zone selector 14 is 0, the third multiplexer 36 outputs the hold signal S4 that is the output signal of the first multiplexer 34.

As described, in the second embodiment, depending on whether the phase difference between the reference signal and the oscillation signal of the DCO 2 is equal to or larger than a predetermined value, the phase shift amount of the phase difference signal output from the edge selector 5 is varied. Therefore, dithering can be performed without widening the input phase range of the TDC 6. Moreover, also in the second embodiment, in the same manner as in the first embodiment, determination of the phase shift amount and of the sign of the phase shift amount can be performed with one parameter that is the duty ratio of the oscillation signal of the DCO 2, and hence dithering can be performed at high speeds without scaling-up the circuitry.

### FOURTH EMBODIMENT

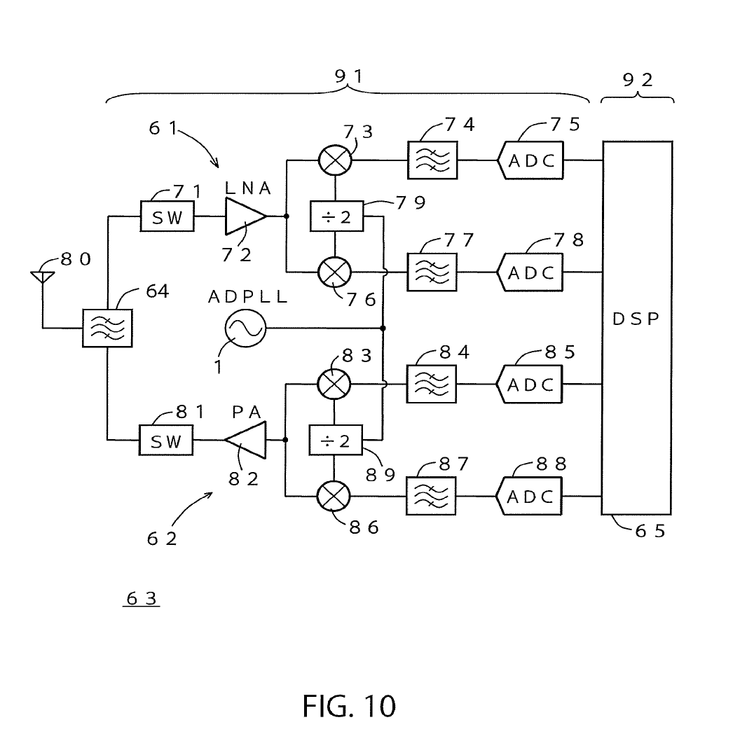

The oscillator 1 in the first or the second embodiment described above can be used in reception circuitry 61 or a wireless communication apparatus 63 provided with the reception circuitry 61 and transmission circuitry 62. FIG. 10 is a block diagram showing the internal configurations of the reception circuitry 61 having the oscillator 1 of ADPLL configuration in the first or the second embodiment and of the wireless communication apparatus 63.

The wireless communication apparatus 63 of FIG. 10 is provided with an RF unit 91 and a base band unit 92. The RF unit 91 has the transmission circuitry 62, the reception circuitry 61, the oscillator 1 for generating a local oscillation signal that is shared by the transmission circuitry 62 and the reception circuitry 61, and a band-pass filter (BPF) 64 connected to an antenna unit 80. The base band unit 92 has a signal processor (DSP) 65 for base band processing. The oscillator 1 of FIG. 10 has the same configuration as the oscillator 1 explained in the first or the second embodiment. The entire wireless communication apparatus 63 of FIG. 10 can be configured with a one-chip IC (Integrated Circuit or semiconductor device). Or the wireless communication apparatus 63 of FIG. 10 may be configured with a plurality of chips. For example, the RF unit 91 and the base band unit 92 may be configured with separate chips. The RF unit 91 may be configured with a plurality of chips. The base band unit 92 may be configured with a plurality of chips.

The reception circuitry 61 has a transmission-reception switch 71, a low-noise amplifier (LNA) 72, an I-signal reception mixer (MIX) 73, a low-pass filter (LPF) 74 and an A/D converter (ADC) 75, a Q-signal reception mixer (MIX) 76, a low-pass filter (LPF) 77 and an A/D converter (ADC) 78, and a frequency divider 79 for dividing the local oscillation signal sent from the oscillator 1.

The transmission circuitry 62 has a transmission-reception switch 81, a power amplifier (PA) 82, an I-signal transmission mixer (MIX) 83, a low-pass filter (LPF) 84 and a D/A converter (DAC) 85, a Q-signal transmission mixer (MIX) 86, a low-pass filter (LPF) 87 and a D/A converter (DAC) 88, and a frequency divider 89 for dividing the local oscillation signal sent from the oscillator 1.

The signal processor 65 is provided with a transmission processing function, a reception processing function, and a MAC (Media Access Control)-layer or network-layer processing function, the network layer being an upper layer of the MAC layer.

A wireless communication apparatus 63 having only the reception circuitry 61 or only the transmission circuitry 62 of FIG. 10 may be provided.

Although the wireless communication apparatus 63 of FIG. 10 is provided with only one antenna unit 80, there is no particular limitation on the number of antennas. For example, a transmission antenna unit 80 and a reception antenna unit 80 may be separately provided. An I-signal antenna unit 80 and a Q-signal antenna unit 80 may be separately provided. In the case of one antenna unit 80, transmission and reception may be switched by a transmission-reception switch.

The wireless communication apparatus 63 shown in FIG. is applicable to a stand-alone wireless communication apparatus 63, such as, an access point, a wireless router and a computer, to a portable wireless terminal, such as, a smartphone and a mobile phone, to a peripheral device, such as a mouse and a keyboard, for wireless communication with a host device, to a card-type device having a wireless function, and to a wearable terminal for biological-information wireless communication. The wireless mode for wireless communication between wireless communication apparatuses 63 each shown in FIG. 10 is not limited to particular one. Applicable wireless modes are cellular communication beyond third generation, wireless LAN, Bluetooth (a registered trademark), near-field wireless communication, etc.

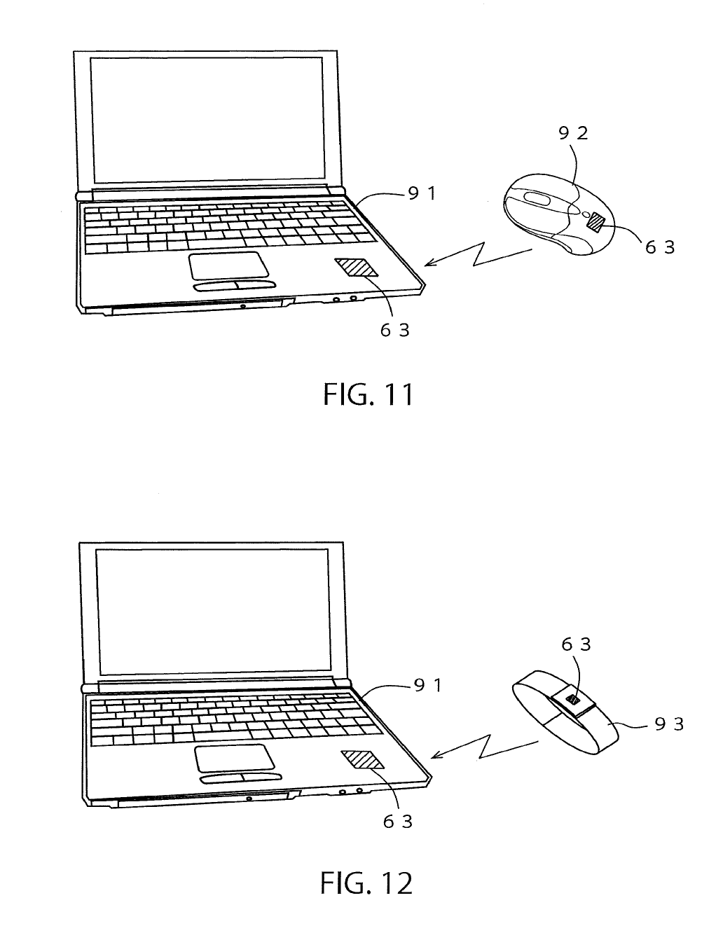

FIG. 11 shows an example of wireless communication between a PC 91 that is a host device and a mouse 92 that is a peripheral device. The wireless communication apparatus 63 shown in FIG. 10 is built in each of the PC 91 and the mouse 92. The mouse 92 uses power of a built-in battery to perform wireless communication. Since there is a limited space for the built-in battery, the mouse 92 is required to perform wireless communication with power consumption as low as possible. For this reason, it is desirable to perform wireless communication with a wireless mode capable of wireless communication with low power consumption, such as Bluetooth Low Energy decided in Bluetooth (a registered trademark)-4.0 standards.

FIG. 12 shows an example of wireless communication between a wearable terminal 93 and a host device (for example, PC 91). The wearable terminal 93 is attached to a human body, which may not only be an arm wearable type such as shown in FIG. 12 but also a variety of types such as a sealing type to be sealed to the human body, an eye-glass type or an earphone type attached to the human body besides arms, and a pace maker or the like embedded inside the human body. Also in the case of FIG. 12, the wearable terminal 93 and the PC 91 both have the wireless communication apparatus 63 shown in FIG. 12 built therein. The PC 91 is a computer, a sever, etc.

Since the wearable terminal 93 is attached to the human body, the space for a built-in battery is limited, it is desirable to adopt a wireless mode capable of wireless communication with low power consumption, such as Bluetooth Low Energy mentioned above.

In the case of wireless communication between wireless communication apparatuses 63 each shown in FIG. 10, the type of information transmitted and received is not limited to any particular one. However, it is desirable to change the wireless mode between the case of transmission and reception of data having a large data amount such as moving image data and the case of transmission and reception of data having a small data amount such as operational information of the mouse 92, requiring to perform wireless communication in the optimum wireless mode depending on the information amount to be transmitted and received.

In the case of wireless communication between wireless communication apparatuses 63 each shown in FIG. 10, a notification unit may be provided to notify a user of an operational state of wireless communication. Examples of the notification unit are, for example, an LED display to indicate the operational state, a vibrator to notify the operational state with vibration, and a speaker or a buzzer to notify the operational state with audio information.

At least part of the oscillator 1 and the wireless communication apparatus 63 explained in each embodiment described above may be configured with hardware or software. When it is configured with software, a program that performs at least part of the oscillator 1 and the wireless communication apparatus 63 may be stored in a storage medium such as a flexible disk and CD-ROM, and then installed in a computer to run thereon. The storage medium may not be limited to a detachable one such as a magnetic disk and an optical disk but may be a standalone type such as a hard disk and a memory.

Moreover, a program that achieves the function of at least part of the oscillator 1 and the wireless communication apparatus 63 may be distributed via a communication network a (including wireless communication) such as the Internet. The program may also be distributed via an online network such as the Internet or a wireless network, or stored in a storage medium and distributed under the condition that the program is encrypted, modulated or compressed.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. An oscillator comprising:
an oscillator unit to generate an oscillation signal having an oscillation frequency in accordance with a phase error signal;
an integer phase detector to detect an integer phase of the oscillation signal;
a random number generator to generate a random number;
an edge selector, based on the random number, to output a phase difference signal indicating a phase difference between a phase of a reference signal and a phase of the oscillation signal, or indicating a phase difference acquired by offsetting the phase difference;
a fractional phase detector to detect a fractional phase of the oscillation signal based on the phase difference signal;
an offset correction arithmetic unit to compute an offset correction value in accordance with the random number; and
a phase error generator to generate the phase error signal based on the integer phase, the fractional phase, the offset correction value, and the reference phase.

2. The oscillator of claim 1, wherein the offset correction arithmetic unit computes the offset correction value by multiplying the random number by a predetermined coefficient so that a phase noise of the oscillation signal is minimalized.

3. The oscillator of claim 1 further comprising a phase-shift direction selector to generate a signal indicating a phase shift direction in the edge selector based on the reference phase and the random number,
wherein the offset correction arithmetic unit computes the offset correction value based on the signal generated by the phase-shift direction selector, and
the edge selector generates the phase difference signal based on the signal generated by the phase-shift direction selector.

4. The oscillator of claim 3, wherein the offset correction arithmetic unit computes the offset correction value so that a phase of the phase difference signal output from the edge selector does not exceed 2π.

5. The oscillator of claim 3, wherein the offset correction arithmetic unit computes the offset correction value including any one of −α, 0, and (1−α), where a is a gain, based on the random number.

6. The oscillator of claim 5, wherein, if a phase of the phase difference signal before offsetting is smaller than (1−α)π, the edge selector randomly determines whether to shift the phase of the phase difference signal before offsetting by +απ, and if the phase of the phase difference signal before offsetting is equal to or larger than (1−α)π, the edge selector randomly determines whether to shift the phase of the phase difference signal before offsetting by (α−1)π.

7. The oscillator of claim 5, wherein the gain α is a duty ratio of the oscillation signal.

8. A semiconductor device comprising an integrated circuit having an oscillator,
wherein the oscillator comprises:
an oscillator unit to generate an oscillation signal having an oscillation frequency in accordance with a phase error signal;
an integer phase detector to detect an integer phase of the oscillation signal;
a random number generator to generate a random number;
an edge selector, based on the random number, to output a phase difference signal indicating a phase difference between a phase of a reference signal and a phase of the oscillation signal, or indicating a phase difference acquired by offsetting the phase difference;
a fractional phase detector to detect a fractional phase of the oscillation signal based on the phase difference signal;
an offset correction arithmetic unit to compute an offset correction value in accordance with the random number; and
a phase error generator to generate the phase error signal based on the integer phase, the fractional phase, the offset correction value, and the reference phase.

9. The semiconductor device of claim 8, wherein the offset correction arithmetic unit computes the offset correction value by multiplying the random number by a predetermined coefficient so that a phase noise of the oscillation signal is minimalized.

10. The semiconductor device of claim 8 further comprising a phase-shift direction selector to generate a signal indicating a phase shift direction in the edge selector based on the reference phase and the random number,
wherein the offset correction arithmetic unit computes the offset correction value based on the signal generated by the phase-shift direction selector, and
the edge selector generates the phase difference signal based on the signal generated by the phase-shift direction selector.

11. The semiconductor device of claim 10, wherein the offset correction arithmetic unit computes the offset correction value so that a phase of the phase difference signal output from the edge selector does not exceed 2π.

12. The semiconductor device of claim 10, wherein the offset correction arithmetic unit computes the offset correction value including any one of −α, 0, and (1−α), where α is a gain, based on the random number.

13. The semiconductor device of claim 12, wherein, if a phase of the phase difference signal before offsetting is smaller than (1−α)π, the edge selector randomly determines whether to shift the phase of the phase difference signal before offsetting by +απ, and if the phase of the phase difference signal before offsetting is equal to or larger than (1−α)π, the edge selector randomly determines whether to shift the phase of the phase difference signal before offsetting by (α−1)π.

14. The semiconductor device of claim 12, wherein the gain α is a duty ratio of the oscillation signal.

15. A wireless communication apparatus comprising an RF unit and a base band unit,
wherein the RF unit comprises transmission circuitry and reception circuitry,
the base band unit comprises transmission processing circuitry and reception processing circuitry, and
the reception circuitry comprises:
an oscillator unit to generate an oscillation signal having an oscillation frequency in accordance with a phase error signal;
an integer phase detector to detect an integer phase of the oscillation signal;
a random number generator to generate a random number;
an edge selector, based on the random number, to output a phase difference signal indicating a phase difference between a phase of a reference signal and a phase of the oscillation signal, or indicating a phase difference acquired by offsetting the phase difference;
a fractional phase detector to detect a fractional phase of the oscillation signal based on the phase difference signal;
an offset correction arithmetic unit to compute an offset correction value in accordance with the random number; and
a phase error generator to generate the phase error signal based on the integer phase, the fractional phase, the offset correction value, and the reference phase.

16. The wireless communication apparatus of claim 15 comprises at least one antenna.

17. The wireless communication apparatus of claim 15, wherein the offset correction arithmetic unit computes the offset correction value by multiplying the random number by a predetermined coefficient so that a phase noise of the oscillation signal is minimalized.

18. The wireless communication apparatus of claim 15 further comprising a phase-shift direction selector to generate a signal indicating a phase shift direction in the edge selector based on the reference phase and the random number,
wherein the offset correction arithmetic unit computes the offset correction value based on the signal generated by the phase-shift direction selector, and
the edge selector generates the phase difference signal based on the signal generated by the phase-shift direction selector.

19. The wireless communication apparatus of claim 18, wherein the offset correction arithmetic unit computes the offset correction value so that a phase of the phase difference signal output from the edge selector does not exceed 2π.

20. The wireless communication apparatus of claim 18, wherein the offset correction arithmetic unit computes the offset correction value including any one of −α, 0, and (1−α), where α is a gain, based on the random number.
